(19) United States
(12) Patent Application Publication
(10) Pub. No.: US 2014/0146500 A1
(43) Pub. Date: May 29, 2014

(54) MULTI-PIECE SUBSTRATE

(71) Applicant: IBIDEN CO., LTD., Ogaki-shi (JP)

(72) Inventors: Keisuke SHIMIZU, Ogaki-shi (JP); Yuichi NAKAMURA, Ogaki-shi (JP); Tsuyoshi YAMAGUCHI, Ogaki-shi (JP)

(73) Assignee: IBIDEN CO., LTD., Ogaki-shi (JP)

(21) Appl. No.: 14/093,135

(22) Filed: Nov. 29, 2013

(30) Foreign Application Priority Data
Nov. 28, 2012 (JP) 2012-259778

(51) Int. Cl. H05K 3/00; H05K 1/18

(52) U.S. Cl. CPC H05K 3/0097; H05K 1/182
USPC 361/761

(57) ABSTRACT

A multi-piece substrate includes a unit component having four sides and including multiple wiring boards arrayed in a matrix, and a frame component supporting the unit component such that the frame component is surrounding an outer periphery of the unit component. Each of the wiring boards has a semiconductor element built therein, and the frame component has multiple slit portions formed such that the slit portions are formed along the four sides of the unit component, respectively.

### CROSS-REFERENCE TO RELATED APPLICATIONS

The present application is based upon and claims the benefit of priority from U.S. application Ser. No. 2012-259778, filed Nov. 28, 2012, the entire contents of which are incorporated herein by reference.

### BACKGROUND OF THE INVENTION

1. Field of the Invention

The present invention relates to a multi-piece substrate used for simultaneously fabricating multiple wiring boards each having a built-in semiconductor element, more particularly to a multi-piece substrate in which unit components each including wiring boards arranged in a matrix are supported by a frame component (outer frame).

2. Description of Background Art

An IC chip may not be mounted on a package substrate but may be built in a printed wiring board. JP 2009-289848 A describes a multi-piece substrate in which notches are provided in a frame component. The entire contents of this publication are incorporated herein by reference.

### SUMMARY OF THE INVENTION

According to one aspect of the present invention, A multi-piece substrate includes a unit component having four sides and including multiple wiring boards arrayed in a matrix, and a frame component supporting the unit component such that the frame component is surrounding an outer periphery of the unit component. Each of the wiring boards has a semiconductor element built therein, and the frame component has multiple slit portions formed such that the slit portions are formed along the four sides of the unit component, respectively.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view of a multi-piece substrate according to a first embodiment of the present invention;

FIG. 2 is a cross-sectional view of a wiring board according to the first embodiment;

FIGS. 3A to 3F are process drawings illustrating a method for manufacturing the multi-piece substrate according to the first embodiment;

FIGS. 4A to 4E are process drawings illustrating the method for manufacturing the multi-piece substrate according to the first embodiment;

FIGS. 5A to 5D are process drawings illustrating the method for manufacturing the multi-piece substrate according to the first embodiment;

FIGS. 6A to 6D are process drawings illustrating the method for manufacturing the multi-piece substrate according to the first embodiment;

FIG. 7 is a plan view of a multi-piece substrate according to a second embodiment of the invention;

FIG. 8 is a plan view of a multi-piece substrate according to a third embodiment of the invention;

FIG. 9 is a plan view of a multi-piece substrate according to a fourth embodiment of the invention; and

FIG. 10 is a plan view of a multi-piece substrate according to a fifth embodiment of the invention.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

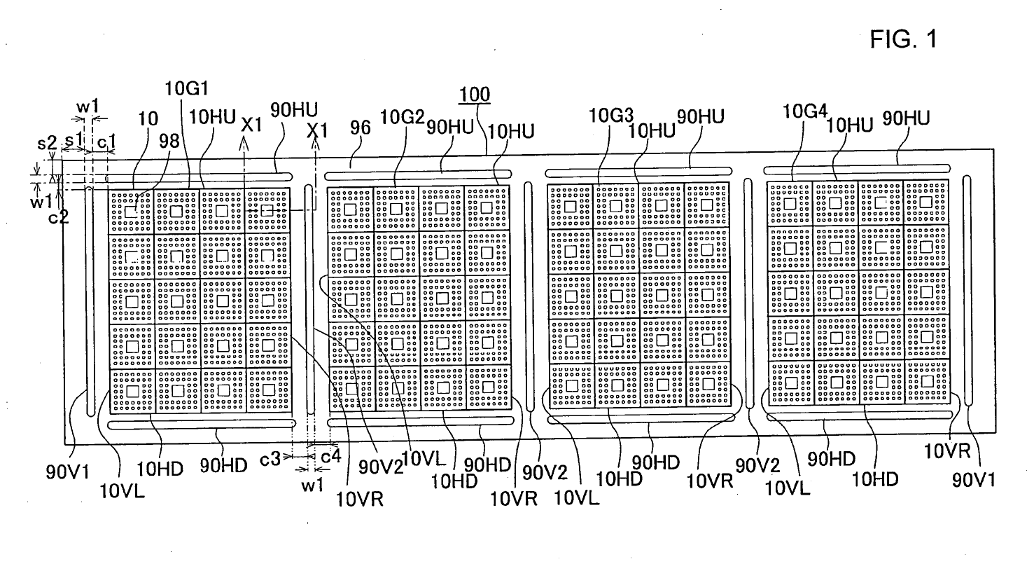

A multi-piece substrate according to a first embodiment of the present invention is illustrated in FIG. 1.

The multi-piece substrate 100 is formed with four unit components (10G1, 10G2, 10G3, 10G4), containing wiring boards 10 each arranged in a matrix of 4×5, and a frame 96 holding the four unit components (10G1, 10G2, 10G3, 10G4) placed in a lateral direction. In the frame 96, slits (90HU) are formed corresponding to respective upper side walls (10HU) of the rectangular unit components (10G1, 10G2, 10G3, 10G4), and slits (90HD) are also formed corresponding to respective lower side walls (10HD) of the unit components (10G1, 10G2, 10G3, 10G4). Likewise, in the frame 96, slits (90V1) are formed corresponding to the left side wall (10VL) and the right side wall (10VR) of the unit component (10G1), respectively. Also, slits (90V2) are formed corresponding to the respective right side walls (10VR) of the unit components (10G1, 10G2, 10G3) as well as corresponding to the respective left side walls (10VL) of the unit components (10G2, 10G3, 10G4).

The widths (w1) of the slits (90HU, 90HD, 90V1, 90V2) are the same as each other, and are set to be at least 0.01 mm but no greater than 10 mm. The length of each of the slits (90HU, 90HD) is longer than the lateral width of each of the unit components (10G1, 10G2, 10G3, 10G4), and the length of each of the slits (90V1, 90V2) is longer than the longitudinal height of each of the unit components (10G1, 10G2, 10G3, 10G4). The space (c2) between the upper side wall (10HU) and the slit (90HU) of the unit component 10G1 is 1 mm, and the space (s2) between the slit (90HU) and the outer edge of the multi-piece substrate is 3 mm. The space between the lower side wall (10HD) and the slit (90HD) and the space between the slit (90HD) and the outer edge of the multi-piece substrate are also set the same as described above. The unit components (10G2 to 10G4) are also each set in the same manner as the unit component (10G1). The space (e1) between the left side wall (10VL) and the slit (90V1) of the unit component (10G1) is 1 mm, and the space (s1) between the slit (90V1) and the outer edge of the multi-piece substrate is 3 mm. The right side of the unit component (10G4) is set in the same manner. The space (c3) between the right side wall (10VR) and the slit (90V2), and the space (c4) between the left side wall (10VL) and the slit (90V2) also each are 1 mm. The slit 90V2 between the unit component (10G2) and the unit component (10G3), and the slit (90V2) between the unit component (10G3) and the unit component (10G4) are also each set in the same manner. That is, the space between each side wall of the unit component and the corresponding slit is uniformly set at 1 mm, and the space between each outer edge of the multi-piece substrate and the corresponding slit is uniformly set at 3 mm. It is preferred to uniformly set the space between each side wall of the unit component and the corresponding slit for the purpose of equalizing stresses to be exerted from four sides to the respective wiring boards 10 of the unit component. To strengthen the frame for supporting the unit components, it is also preferred to make the space between each outer edge of the multi-piece substrate and the corresponding slit wider than the space between each side wall of the unit component and the corresponding slit.

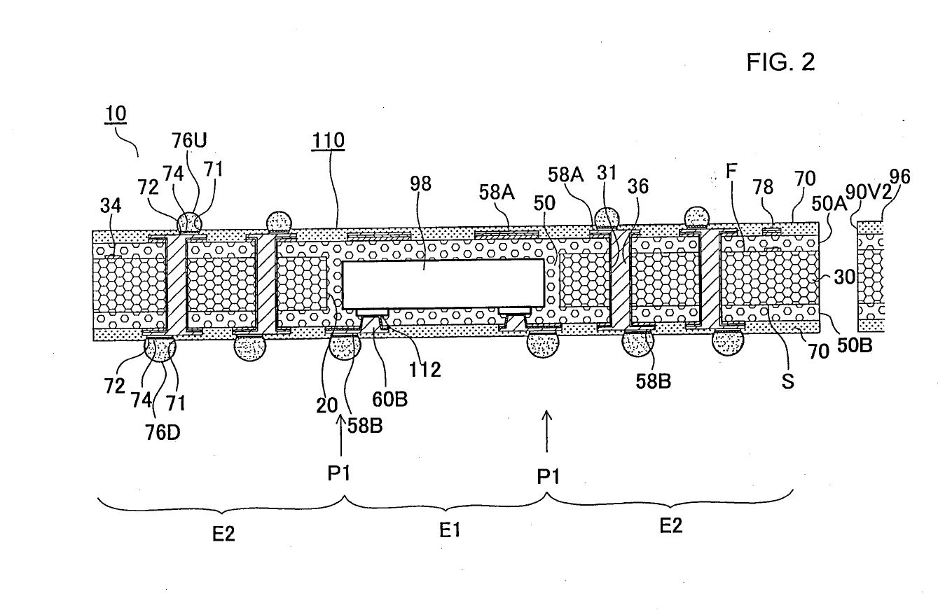

A cross-sectional view taken from line X1-X1 in FIG. 1 is illustrated in FIG. 2. The wiring board 10 is provided with an insulative base material 30 having a first surface (F) and a second surface (S) opposite the first face. The insulative base material 30 is provided with a through hole 20, and a semiconductor element 98 is accommodated in this through hole 20.

On both the first surface (F) of the insulative base material 30 and the semiconductor element 98, a first buildup layer is formed. The first buildup layer includes an insulation layer (50A), which is formed to cover both the first surface (F) of the insulative base material 30 and the semiconductor element 98, a conductive layer (58A) on the insulation layer (50A), and an alignment mark 78. A second buildup layer is formed on both the second surface (S) of the insulative base material 30 and the semiconductor element 98. The second buildup layer includes an insulation layer (50B), which is formed to cover both the second surface (S) of the insulative base material 30 and the semiconductor element 98, and a conductive layer (58B) on the insulation layer (50B). A through hole 31 is formed to penetrate through the insulative base material 30, insulation layer (50A) and insulation layer (50B); in the through hole 31, a through-hole conductor 36 is formed by filling a plating film. The end portion of the through-hole conductor 36 on its first-surface side is connected to the conductive layer (58A) on the insulation layer (50A), and the end portion of the through-hole conductor 36 on its second-surface side is connected to the conductive layer (58B) on the insulation layer (50B). In the insulation layer (50B), a via conductor (60B) is formed for connection to a connection terminal 112 of the semiconductor element 98, and the end portion of the via conductor (60B) on its second-surface side is connected to the conductive layer (58B) on the insulation layer (50B).

On each of the first buildup layer and the second buildup layer, there is formed a solder resist layer 70 having an opening 71. Each of the conductive layers (58A, 58B) exposed through the opening 71 of the solder resist layer 70 functions as a pad. Metal films (72, 74) made of Ni/Au, Ni/Pd/Au, or the like are formed on the pad, and solder bumps (76U, 76D) are formed on the metal films (72, 74), respectively. An IC chip is mounted onto the multi-piece substrate through the solder bump (76U). After the IC chip has been mounted, the wiring board 10 is separated from the multi-piece substrate by being cut into pieces, and is mounted onto a motherboard through the solder bump (76D).

In the wiring board 10 of the first embodiment, when stress is exerted on the border (P1) between the area (E1) where the semiconductor element 98 is accommodated and the area (E2) outside the semiconductor element 98 due to the thermal contraction difference between the semiconductor element 98 and the resin in the wiring board 10, the area (E1) where the semiconductor element 98 is accommodated is subjected to outward pushing force in a vertical direction. However, the stress is apt to be released to the outside of the wiring board 10, and the wiring board 10 resists warping due to the slits provided on four sides of the unit components.

In the multi-piece substrate of the first embodiment, since the slits (90HU, 90HD, 90V1, 90V2) are formed at positions corresponding to the respective four sides of each of the unit components (10G1, 10G2, 10G3, 10G4), the wiring boards 10 are not subjected to stresses caused by thermal expansion of the frame 96 in a reflow process. Thus, warping seldom occurs even in the area (E2), which is outside the area (E1) where the semiconductor element is accommodated and tends to warp.

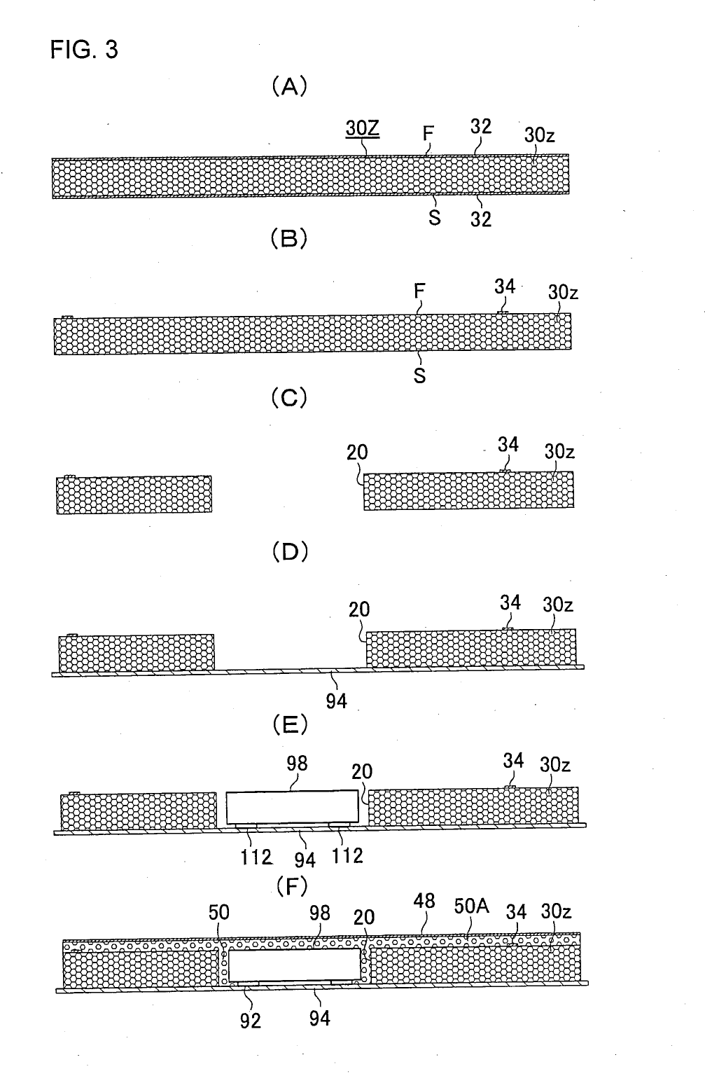

A method for manufacturing the wiring board 10 of the first embodiment is illustrated in FIGS. 3A to 3F to FIGS. 6A to 6D.

(1) A double-sided copper-cladded laminate (30Z) made of the insulative base material (30z) and copper foils 32 laminated on the both sides thereof is a starting material. The insulative base material (30z) has the first surface (F) and second surface (S) opposite the first surface. Blackening processing is performed on the surface of the copper foil 32 (not illustrated) (refer to FIG. 3A).

(2) The copper foil 32 is patterned, and an alignment mark 34 is formed on the first surface (F) of the insulative base material (30z).

(3) Positioning is conducted with reference to the alignment mark 34, and laser is irradiated at the insulative base material (30z) to form a through hole 20 therein (refer to FIG. 3C).

(4) On the second surface (S) of the insulative base material 30, a tape 94 is attached, and the through hole 20 is covered with the tape 94 (refer to FIG. 3D). An example of the tape 94 is a PET film.

(5) On the tape 94 exposed through the through hole 20, the semiconductor element 98 is placed by being positioned using the alignment mark 34 (refer to FIG. 3E).

(6) On the first surface (F) of the insulative base material (30z), B-stage prepreg and a copper foil 48 are laminated. Resin is squeezed out from the prepreg by hot pressing and enters the through hole 20. The through hole 20 is filled with a filling resin (resin filler) 50 and an insulation layer (50A) is also formed at that time (refer to FIG. 3F). The gap between the inner wall of the through hole 20 and the semiconductor element 98 is filled with the filling resin 50, and the semiconductor element 98 is secured to the insulative base material (30z). An interlayer insulation-layer resin film may be laminated instead of the prepreg. The prepreg has a reinforcing material such as a glass fiber cloth or the like, while the interlayer insulation-layer resin film does not contain any reinforcing material. Both of them are preferred to contain inorganic particles such as glass particles or the like. The filling resin 50 contains inorganic particles such as silica particles or the like.

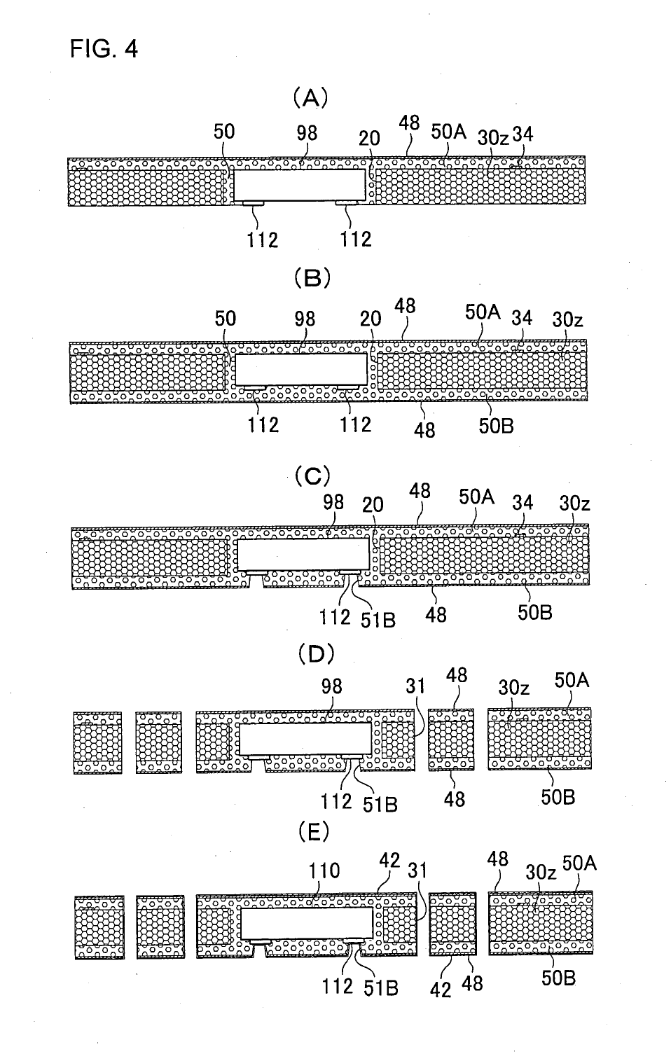

(7) After the tape 94 has been removed, residues on electrodes 112 of the semiconductor element 98 are removed through plasma treatment (refer to FIG. 4A).

(8) On the second surface (S) of the insulative base material (30z), the B-stage prepreg and the copper foil 48 are laminated. The prepregs on the first and second surfaces of the insulative base material (30z) are cured, and the insulation layers (interlayer resin insulation layer) (50A, 50B) are formed on the first and second surfaces of the insulative base material (30z) (refer to FIG. 4B).

(9) By irradiating a CO2 laser at the second surface (S), openings (51 B) are formed in the insulation layer (50B) so as to connect via conductors to the electrodes 112 of the semiconductor element 98 (refer to FIG. 4C).

(10) Using a CO2 laser or a drill, through holes 31 are formed, penetrating through the insulation layer (50A), insulative base material (30z) and insulation layer (50B) (refer to FIG. 4D).

(11) On the copper foils 48 and the inner wall of the openings (51B), electroless plating is performed to form electroless plating films 42 (refer to FIG. 4E).

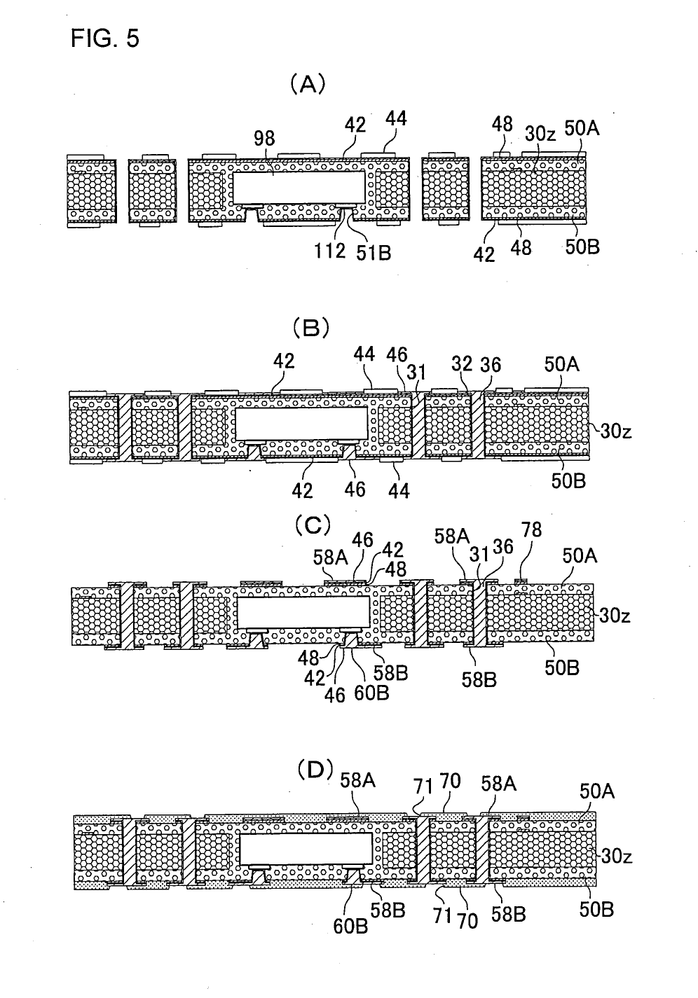

(12) On the electroless plating films 42, plating resists 44 are formed (refer to FIG. 5A).

(13) On the electroless plating film 42 exposed from the plating resists 44, electrolytic plating is performed to form an electrolytic-plated film 46 and to fill the through hole 31 with the electrolytic-plated film 46 (refer to FIG. 5B).

(14) The plating resist 44 is removed using 5% NaOH. Then, the electroless-plated film 42 and the copper foil 48 exposed from the electrolytic-plated film 46 are etched away, and there are thereby formed the conductive layers (58A, 58B), alignment mark 78, via conductors (60B) and through-hole conductors 36, each made up of the copper foil 48, electroless-plated film 42 and electrolytic-plated film 46 (refer to FIG. 5C).

(15) On each of the insulation layers (50A, 50B), a solder-resist layer 70 having openings 71 is formed (refer to FIG. 5D). The openings 71 expose portions of conductive layers (58A, 58B), and the exposed portions each function as a pad.

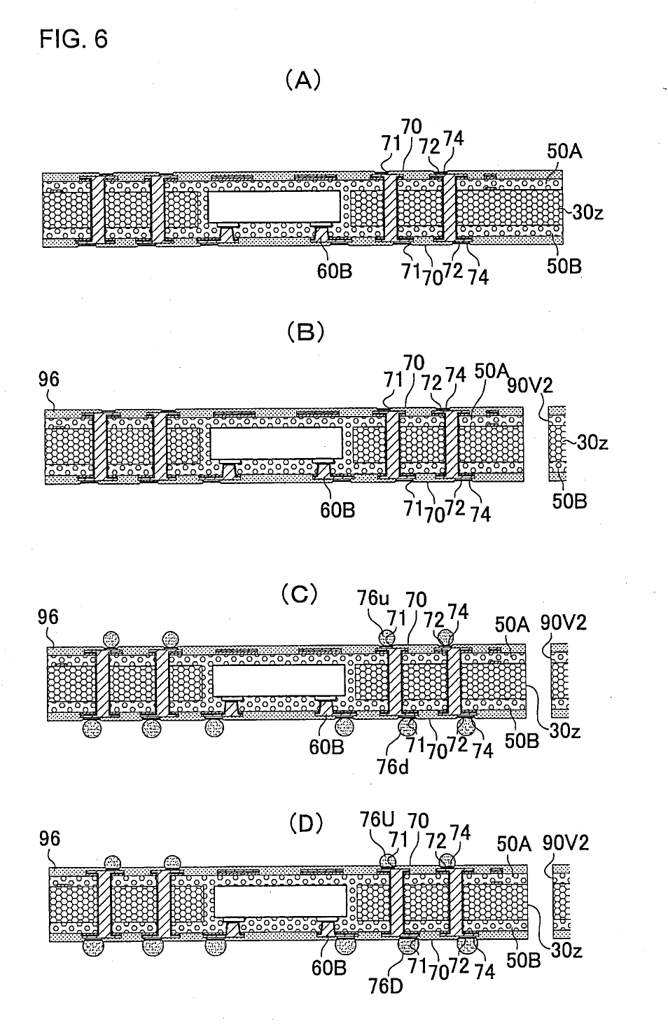

(16) On the pad in the opening 71, a metal film made of a nickel layer 72 and a gold layer 74 on the nickel layer 72 is formed (refer to FIG. 6A). Instead of the nickel/gold layer, another metal layer made of nickel, palladium and gold layers may also be used. In the wiring board 10 illustrated in FIG. 2, the via conductors (60B) are provided only in the second buildup layer.

(17) Slits (90V2, 90V1, 90HU, 90HD) are formed through router processing or laser processing (refer to FIG. 6B). The plan view of the slits (90V2, 90V1, 90HU, 90HD) is shown in FIG. 1. The slit width is preferred to be approximately 0.5 mm to 1 mm when router processing is employed, and to be approximately 0.03 mm to 0.2 mm when laser processing is employed. If a slit width is at least 0.01 mm, the slit works. If a slit width exceeds 10 mm, it is not desirable because the external dimension of the multi-piece substrate is enlarged and manufacturing costs rise.

(18) After that, a solder ball (76u) is placed on the pad of the first buildup layer, and another solder ball (76d) is placed on the second buildup layer (refer to FIG. 6C).

(19) Through reflow processing, the solder bump (76U) is formed on the pad of the first buildup layer, and the solder bump (76D) is formed on the pad of the second buildup layer (refer to FIG. 6D). At this occasion, since the slits (90V2, 90V1, 90HU, 90HD) are provided on the outer periphery of the unit component as described above, the wiring boards 10 are not subjected to stress caused by thermal expansion of the frame 96 in the reflow process, and are unlikely to warp.

An IC chip is mounted on each wiring board 10 through the solder bump (76U). After that, the wiring board 10 is separated from the multi-piece substrate by being cut into pieces, and is mounted onto a motherboard through the solder bump (76D) (not illustrated).

### Second Embodiment

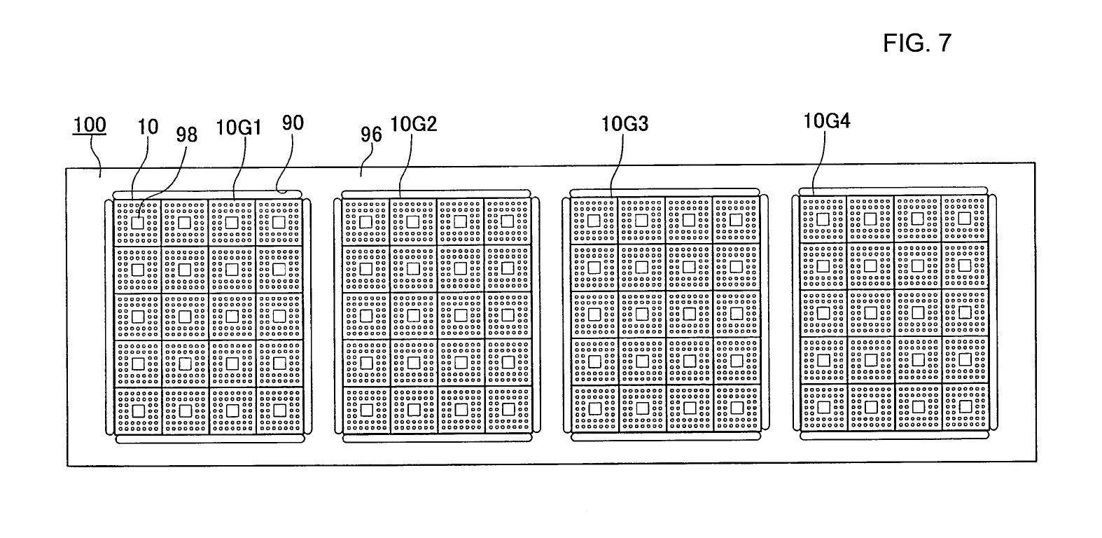

FIG. 7 illustrates a multi-piece substrate 100 according to a second embodiment of the invention.

In the multi-piece substrate 100 of the second embodiment, slits 90 are provided so as to be directly on or in contact with the four peripheral edges of each of unit components (10G1, 10G2, 10G3, 10G4). In the second embodiment, two lines of the slit 90 are provided between the unit components (10G1, 10G2), the unit components (10G2, 10G3), and the unit components (10G3, 10G4), respectively. In the second embodiment, there is such an advantage that the size of the multi-piece substrate 100 is reduced and separating the wiring boards into pieces is made easier.

### Third Embodiment

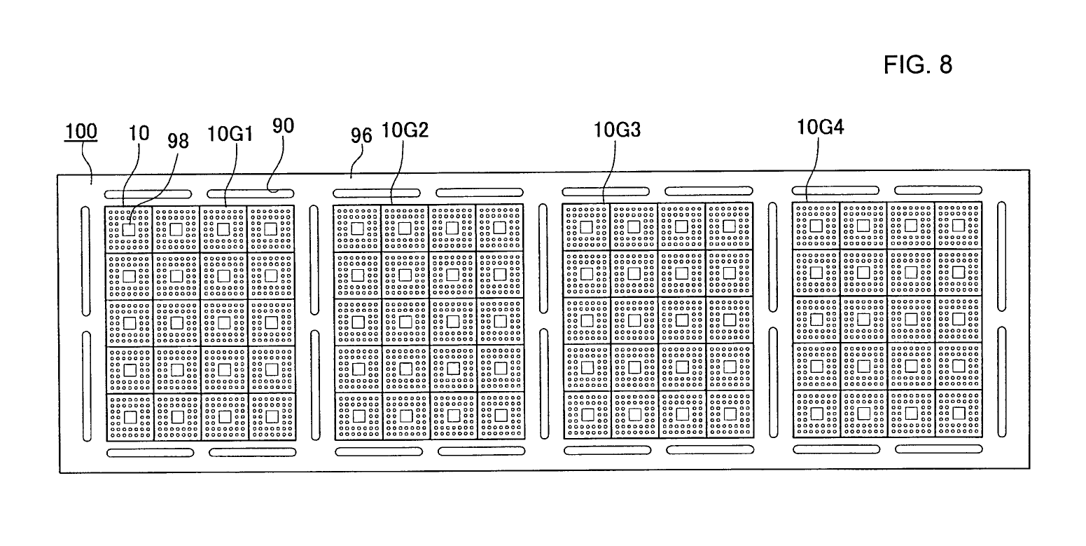

FIG. 8 illustrates a multi-piece substrate 100 according to a third embodiment of the invention.

In the multi-piece substrate 100 of the third embodiment, slits 90 are each divided into two portions. The third embodiment allows the multi-piece substrate 100 to maintain its rigidity.

### Fourth Embodiment

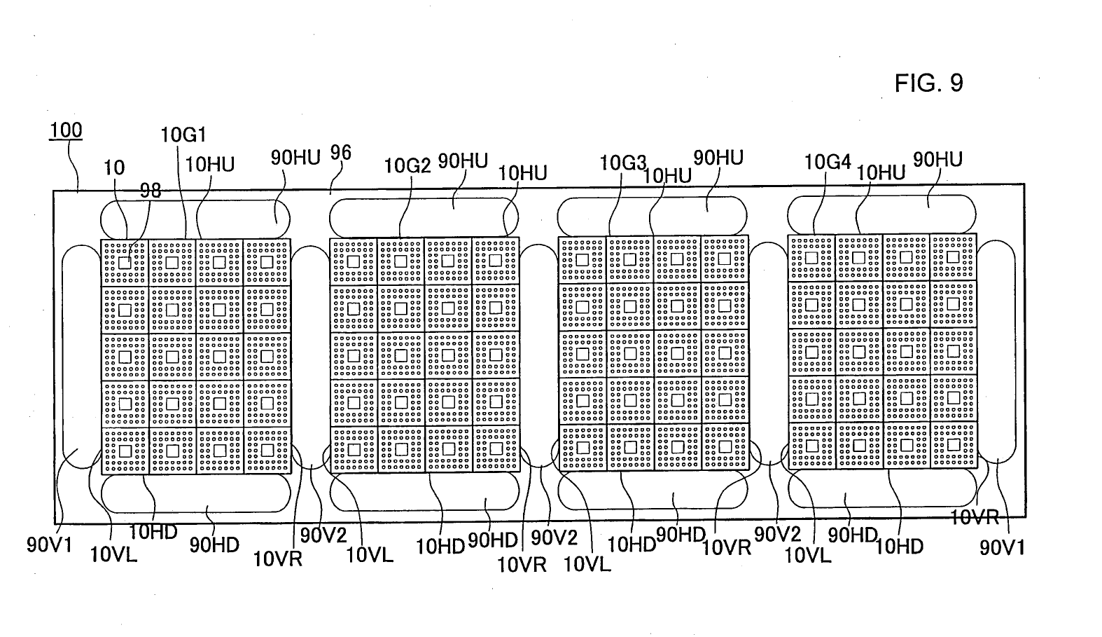

FIG. 9 illustrates a multi-piece substrate 100 according to a fourth embodiment of the invention.

In the fourth embodiment, a slit (90V2) is provided so as to extend across from the right side wall (10VR) of a unit component (10G1) to the left side wall (10VL) of a unit component (10G2). Likewise, slits (90V2) are provided so as to extend across from the right side wall (10VR) of the unit component (10G2) to the left side wall (10VL) of a unit component (10G3), and also so as to extend across from the right side wall (10VR) of the unit component (10G3) to the left side wall (10VL) of a unit component (10G4). In addition, slits (90V1) adjacent to the left side wall (10VL) of the unit component (10G1) and also adjacent to the right side wall (10VR) of the unit component (10G4), slits (90HU) adjacent to upper side walls (10HU) of the unit components, and slits (90HD) adjacent to lower side walls (10HD) of the unit components are each formed in the same shape as the slit (90V2). In the fourth embodiment, stress exerted on the respective wiring boards 10 is minimized.

### Fifth Embodiment

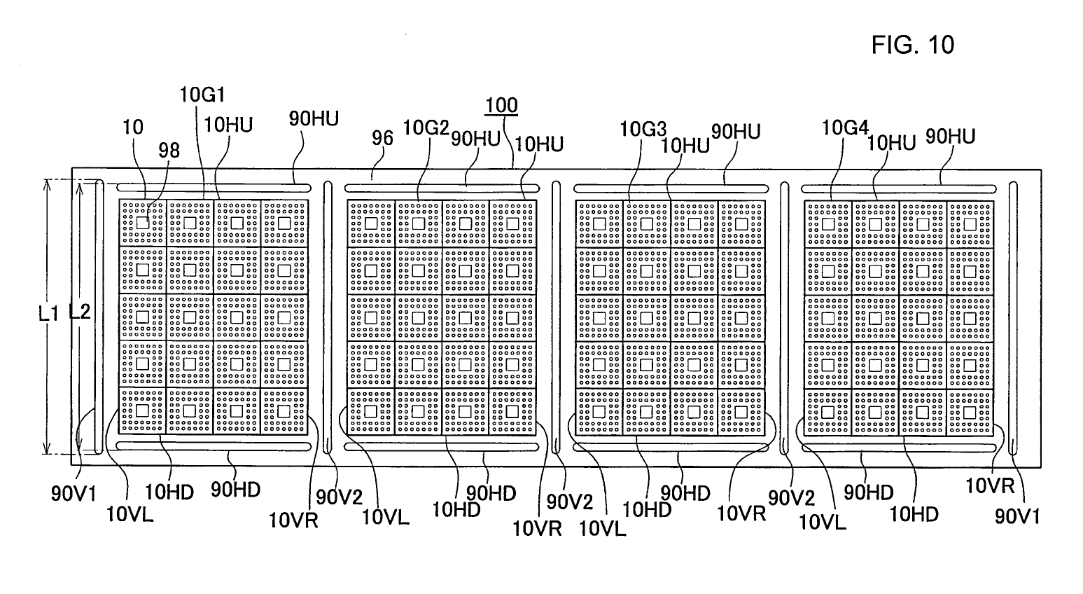

FIG. 10 illustrates a multi-piece substrate 100 according to a fifth embodiment of the invention.

The multi-piece substrate 100 of the fifth embodiment is structured such that the length (L1) of slits (90V1, 90V2) in the longitudinal direction is set longer than the distance (L2) from the outer edge of slits (90HU) adjacent to the upper side walls (10HU) of unit components to the outer edge of slits (90HD) adjacent to the lower side walls (10HD). In the multi-piece substrate 100 of the fifth embodiment, when 4×5 wiring boards 10 are formed in one unit component, i.e., the numbers of wiring boards 10 arranged in lateral and longitudinal directions are different from each other, the longitudinal stress and lateral stress exerted on the respective wiring boards 10 are adjustable.

When a semiconductor element is built into a wiring board, due to the difference in the thermal contraction amount or rate between the semiconductor element and the resin in the wiring board, stress is exerted on the border between the area where the semiconductor element is accommodated and the area outside the semiconductor element, and the area where the semiconductor element is accommodated is subjected to force pushing outward in a vertical direction. Accordingly, the wiring board is apt to warp.

In addition, since a frame component holds unit components in which multiple wiring boards are each formed with a built-in semiconductor element, the frame component thermally expands in a reflow process, and compressive stress generated from the frame component is exerted on the wiring boards. At that time, because the semiconductor element less susceptible to warping, the wiring boards outside the semiconductor elements are apt to warp.

In the case in which large-sized semiconductor elements are built into a multi-piece substrate, the rigidity of the multi-piece substrate may become too high. Therefore, it may become difficult to manufacture the multi-piece substrates using the same production line as that for ordinary wiring boards without built-in components.

A multi-piece substrate according to an embodiment of the present invention includes a unit component including multiple wiring boards arranged in a matrix, the wiring boards each having a built-in semiconductor element, and a frame component formed on a periphery of the unit component. The frame component has slits formed at positions corresponding to respective four sides of the unit component.

In a multi-piece substrate according to an embodiment of the present invention, the slits are formed at positions corresponding to the respective four sides of the unit component, and the wiring boards are not subjected to stress from thermal expansion of the frame component in a reflow process and are therefore not apt to warp. Moreover, when stress is exerted on the border between the area where the semiconductor element is accommodated and the area outside the semiconductor element due to the thermal contraction difference between the semiconductor element and the resin in the wiring boards, the area where a semiconductor element is accommodated is subjected to outward pushing force in a vertical direction. However, the stress tends to be released to the outside of the wiring boards because of the slits formed at positions corresponding to the respective four sides of the unit component. Thus, the wiring boards are not likely to warp. Even when a multi-piece substrate has large-sized built-in semiconductor elements, the rigidity of the multi-piece substrate is lessened due to the slits, and the multi-piece substrate can be manufactured using the same production line as that for ordinary wiring boards.

Obviously, numerous modifications and variations of the present invention are possible in light of the above teachings. It is therefore to be understood that within the scope of the appended claims, the invention may be practiced otherwise than as specifically described herein.

What is claimed is:

1. A multi-piece substrate, comprising:
a unit component having four sides and comprising a plurality of wiring boards arrayed in a matrix; and
a frame component supporting the unit component such that the frame component is surrounding an outer periphery of the unit component,
wherein each of the wiring boards has a semiconductor element built therein, and the frame component has a plurality of slit portions formed such that the slit portions are formed along the four sides of the unit component, respectively.

2. The multi-piece substrate according to claim 1, wherein the slit portions of the frame component are formed such that each of the slit portions has a length which is greater than a length of a respective one of the four sides of the unit component.

3. The multi-piece substrate according to claim 1, wherein the unit component is formed in a plurality, the frame component is supporting the plurality of unit components such that the frame component is surrounding an outer periphery of each of the unit components, and the frame component has one of the slit portions formed between adjacent ones of the plurality of unit components.

4. The multi-piece substrate according to claim 1, wherein the unit component is formed in a plurality, the frame component is supporting the plurality of unit components such that the frame component is surrounding an outer periphery of each of the unit components, and the plurality of slit portions of the frame component includes slit portions formed between adjacent ones of the plurality of unit components such that the frame component has two slit portions between adjacent ones of the plurality of unit components.

5. The multi-piece substrate according to claim 1, wherein the unit component is formed in a plurality, the frame component is supporting the plurality of unit components such that the frame component is surrounding an outer periphery of each of the unit components, the plurality of unit components is positioned in a lateral direction, the plurality of slit portions of the frame component includes a slit portion formed in a longitudinal direction between adjacent ones of the unit components such that the slit portion is formed in a mid-point between the adjacent ones of the unit components, and the plurality of slit portions of the frame component includes slit portions formed in the lateral direction such that a distance between the slit portions in the lateral direction and respective lateral sides of the four sides of each of the unit components is equal to a distance from the slit portion in the longitudinal direction to the adjacent ones of the unit components.

6. The multi-piece substrate according to claim 1, wherein the plurality of slit portions includes at least one slit portion comprising a plurality of divided opening sections.

7. The multi-piece substrate according to claim 1, wherein each of the slit portions comprises a plurality of divided opening sections.

8. The multi-piece substrate according to claim 1, wherein the plurality of slit portions is formed such that a distance from the slit portions to the four sides of the unit component is smaller than a distance from the slit portions to an outer periphery of the frame component.

9. The multi-piece substrate according to claim 1, wherein the plurality of slit portions includes at least one slit portion having a width in a range of from 0.01 mm to 10 mm.

10. The multi-piece substrate according to claim 1, wherein each of the slit portions has a width which is in a range of from 0.01 mm to 10 mm.

11. The multi-piece substrate according to claim 1, wherein the slit portions of the frame component are formed such that each of the slit portions has a length which is greater than a length of a respective one of the four sides of the unit component, the unit component is formed in a plurality, and the frame component has one of the slit portions formed between adjacent ones of the plurality of unit components.

12. The multi-piece substrate according to claim 1, wherein the plurality of slit portions is formed directly on four peripheral edges of the four sides of the unit component.

13. The multi-piece substrate according to claim 1, wherein the plurality of slit portions is formed directly on four peripheral edges of the four sides of the unit component, the unit component is formed in a plurality, and the plurality of slit portions includes slit portions formed between adjacent ones of the plurality of unit components.

14. The multi-piece substrate according to claim 1, wherein the plurality of slit portions is formed directly on four peripheral edges of the four sides of the unit component, the plurality of slit portions includes at least one slit portion comprising a plurality of divided opening sections.

15. The multi-piece substrate according to claim 1, wherein the plurality of slit portions is formed directly on four peripheral edges of the four sides of the unit component, each of the slit portions comprises a plurality of divided opening sections.

16. The multi-piece substrate according to claim 1, wherein the plurality of slit portions is formed directly on four peripheral edges of the four sides of the unit component, the plurality of slit portions includes at least one slit portion having a width in a range of from 0.01 mm to 10 mm.

17. The multi-piece substrate according to claim 1, wherein the plurality of slit portions is formed directly on four peripheral edges of the four sides of the unit component, each of the slit portions has a width which is in a range of from 0.01 mm to 10 mm.

18. The multi-piece substrate according to claim 1, wherein the slit portions of the frame component are formed such that each of the slit portions has a length which is greater than a length of a respective one of the four sides of the unit component, the unit component is formed in a plurality, and the plurality of slit portions includes slit portions formed between adjacent ones of the plurality of unit components.
